(19) United States
(12) Patent Application Publication
(10) Pub. No.: US 2007/0031736 A1
(43) Pub. Date: Feb. 8, 2007

(54) Method and apparatus for compensating for the effects of gravity on pellicle used for protecting a reticle from contamination

(75) Inventors: Marinus Antonius Dimphna Maria Loos, Eindhoven (NL); Rudolf Maria Josef Voncken, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILLIPS ELECTRONICS N.V., 5621 BA EINDHOVEN (NL)

(21) Appl. No.: 10/572,469

(22) PCT Filed: Sep. 2, 2004
(86) PCT No.: PCT/IB04/51669

§ 371 Date: Mar. 20, 2006

(30) Foreign Application Priority Data
Sep. 23, 2003 (EP) 03103511.6

(51) Int. Cl. G03F 1/00

(52) U.S. Cl. 430/5

(57) ABSTRACT

A pellicle membrane (1) is connected to a frame (3), substantially parallel to a reticle base plate (5), so as to define an enclosure with a space (9) between the reticle carried on the base plate (5) and the pellicle membrane (1). A mask (6) is provided on the reticle within the enclosure. A bore hole (11) is provided in a side wall of the frame (3) into the enclosure. A mechanism (13) for adjusting the air pressure in the space (9) to compensate for the effect of gravity on the pellicle membrane (11), comprises a piston member (15) within a housing (17) which is closed at one end, so that a chamber (19) is defined at the closed end of the housing (17). A bore hole (21) is provided in a wall of the housing (17) into the chamber (19) and a tube or pipe (23) between the bore hole (11) and the bore hole (21) defines a gas path between the space (9) and the chamber (19). A moveable said piston member (15) determines the necessary gas pressure in said space (9), to compensate for the effect of gravity on said pellicle membrane (1). Fine tuning can be achieved by changing the mass of the piston member (15) by, for example, attaching weights (25) thereto.

This invention relates to a method and apparatus for protecting a reticle used in chip production from contamination and, more particularly, to a method and apparatus for compensating for the gravitational effects on such a pellicle.

Patterned lithographic masks are utilised in semiconductor chip fabrication, and such lithographic masks need to be protected from particle contamination since foreign matter on a mask will produce a printed defect in the electronic circuit being created on a silicon wafer.

For current lithographic manufacture of semiconductor chips, masks are enclosed in a “pellicle” (currently 1 micrometer polyamide) to protect them from particles. The mask consists of a rigid substrate with a patterned absorbing film on one surface. A pellicle is a thin membrane, stretched over a frame mounted to the mask substrate, which prevents particles from striking patterned areas of the mask. The pellicle is offset from the mask in an “out of focus” image plane, producing a gap between the mask surface (requiring protection) and the pellicle. This offset ensures that particles intercepted by the pellicle do not produce image defects.

For the photon wavelengths used in earlier chip manufacture techniques (365 nm, 248 nm), the pellicle is highly transparent and allows the lithographic radiation to be transmitted to the mask with high efficiency. Pellicles stay affixed to the mask mounting hardware throughout the life of the mask and allow the mask to be handled and inspected free from defect-producing particle contamination.

The next generation of lithographic techniques, including 157 nm optical projection lithography, utilise ionising radiation (photons, ions and electrons, respectively) to perform lithographic imaging. Thus, the masks used in these next generation lithographic techniques are irradiated with ionising radiation during the lithographic exposure. A traditional pellicle cannot be used next generation lithography because the pellicle would absorb too much of the ionising radiation. A membrane might also degrade in the ionising beam, eventually failing and allowing the mask to become contaminated. Furthermore, a traditional pellicle would not survive transfer from atmospheric pressure into the vacuum environment (˜10⁻⁶ Torr) needed for the new generation lithographic techniques. A sealed pellicle/mask assembly would have a trapped air space, which would burst through the thin membrane when the mask is placed in a vacuum environment.

We have now devised an improved arrangement.

In accordance with the present invention, there is provided apparatus for protecting a reticle used for semiconductor chip fabrication, the apparatus comprising an enclosure defined by a pellicle membrane disposed over said reticle with a space therebetween, and means for adjusting gas pressure in said space to compensate for the effect of gravity on said pellicle membrane, the apparatus being characterized in that said means for adjusting gas pressure comprises a piston arrangement comprising a piston member within a housing so as to define a chamber, said chamber being in gas communication with said space between said pellicle membrane and said reticle, whereby adjustment of the size of said chamber by movement of said piston member results in an adjustment in gas pressure within said enclosure so as to compensate for the effect of gravity on said pellicle membrane.

Also in accordance with the present invention, there is provided a method of protecting a reticle used for semiconductor chip fabrication, the method comprising the steps of providing a pellicle membrane over said reticle so as to define an enclosure with a space therebetween, and adjusting gas pressure in said space to compensate for the effect of gravity on said pellicle membrane, the method being characterized in that said step of adjusting gas pressure comprises the steps of providing a piston arrangement comprising a piston member within a housing so as to define a chamber, said chamber being in gas communication with said space between said pellicle membrane and said reticle, whereby movement of said piston member results in an adjustment in gas pressure within said enclosure so as to compensate for the effect of gravity on said pellicle membrane.

Further in accordance with the present invention, there is provided a method of manufacturing a semiconductor chip, the method comprising providing a reticle and apparatus as defined above, providing a patterned mask on said reticle, and irradiating said reticle through said pellicle membrane and said mask.

Still further in accordance with the present invention, there is provided a semiconductor chip fabricated according to the method defined above.

In a preferred embodiment of the invention, the piston arrangement includes a housing which is closed at one end and within which the piston member is disposed to define a chamber at the closed end. A wall of the chamber is preferably provided with an aperture by means of which the chamber is connected by a pipe or tube to said enclosure via an aperture in a side wall thereof.

The arrangement beneficially comprises a piston member having a diameter less than the inner diameter of the housing, said piston member being connected to the inner side walls of the housing in an air-tight manner for example by means of a flexible membrane. This minimises friction between the piston member and the inner wall of the housing, and ensures that there is no absolute gas flow between the piston member and the inner wall of the housing.

In a preferred embodiment, means may be provided to change the mass of the piston member so as to fine tune the compensating mechanism. Such means may comprise weights or the like, which can be selectively added to or removed from the piston member.

Thus, the present invention provides an effective mechanism for adjusting gas pressure in the space between the reticle and the pellicle membrane, so as to compensate for the adverse effects of gravity on the pellicle membrane. The required adjustment is achieved and controlled in a passive way, and fine tuning can be achieved by changing the mass of the piston member. The mechanism may be located near or attached to a reticle base plate (i.e. the plate supporting the reticle), or it may be set apart, as required. As explained above, in a preferred embodiment, friction between the piston member and the inner wall of the housing is minimised and there is no absolute gas flow between the piston member and the inner wall of the housing.

The pellicle membrane is preferably formed of silicon glass. The apparatus preferably comprises a reticle base plate on which the reticle is supported, and a support frame to which the reticle base plate and the pellicle membrane are connected.

These and other aspects of the invention will be apparent from, and elucidated with reference to, the embodiment described herein.

An embodiment of the present invention will now be described by way of example only and with reference to the accompanying drawings, in which:

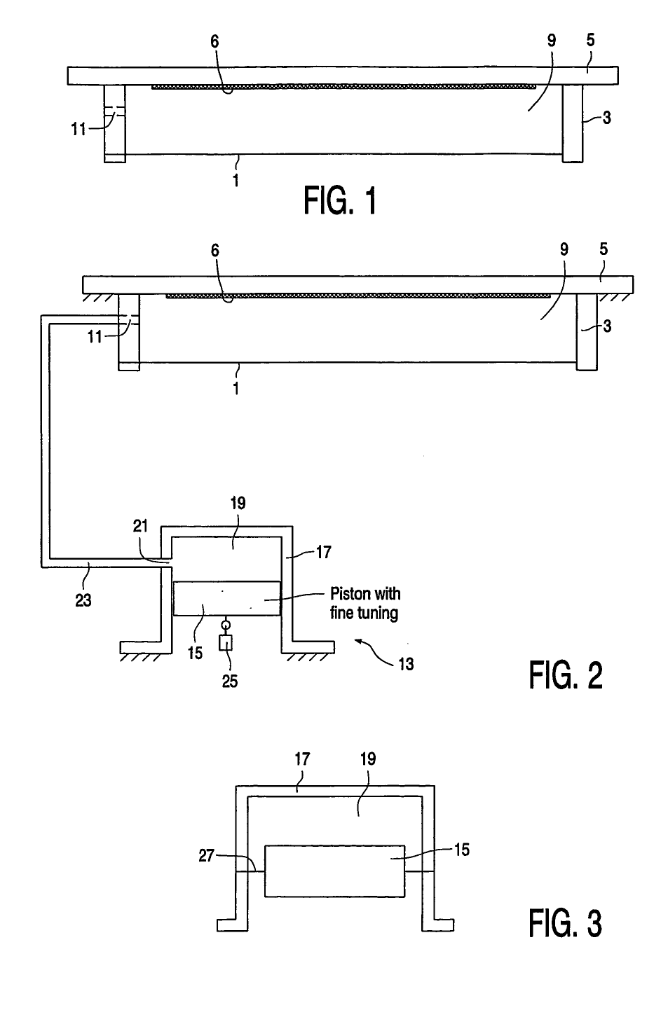

FIG. 1 is a schematic cross-sectional view of a conventional pellicle mounted on a reticle;

FIG. 2 is a schematic cross-sectional view of apparatus according to an exemplary embodiment of the present invention; and

FIG. 3 is a schematic cross-sectional diagram of a piston arrangement for use in apparatus according to an exemplary embodiment of the present invention.

Referring to FIG. 1 of the drawings, a conventional arrangement comprises a thin pellicle membrane 1 and a frame 3. The pellicle membrane 1 is adhered to the frame 3, and a reticle base plate 5, carrying a reticle (i.e. a photolithographic surface) on one side thereof, is adhered to the frame 3 such that there is a gap between the reticle base plate 5 and the membrane 1. In order to equalise the pressure between the space 9 between the reticle base plate 5 and the pellicle membrane 1, and the surrounding atmosphere, a bore hole 11 with a filter is provided in the frame 3.

Such a pellicle, as shown in FIG. 1, comprises a transparent pellicle membrane made of a highly light-transmissive material, such as 1 micrometer polyamide. A mask 6 is provided on one side of the reticle base plate 5 (over the reticle) and the reticle is then exposed to light (through the pellicle 1 and the mask 6) to create the required circuit configuration on the base plate 5.

The resolution of lithography has gradually become higher in recent years, and realise such resolution, light of a shorter wavelength has gradually come to be used as a light source. Specifically, for example, the use of a fluorine excimer laser (157 nm) is becoming increasingly desirable. However, conventional pellicle materials absorb radiation at 157 nm. Thus, the use of glass plates composed of an inorganic compound (such as silicon glass) or the like as the pellicle membrane has been considered.

When these inorganic compounds are used as the pellicle membrane, the membrane should ideally have a thickness of 0.1 mm or more to give the membrane the required strength. However, practically, the plate must be significantly thinner than that to avoid distortion of the radiation and such a plate may become curved due to gravity force, which may cause deviation of the light path for light exposure at the pellicle membrane surface, and thus adversely affect the light exposure.

U.S. patent application Ser. No. US 2001/0004508 describes an arrangement in which the pellicle membrane comprises a thin glass plate adhered to a frame under a photomask such that the membrane tends to warp downwardly due to gravity. However, by decompressing the air in the space between the pellicle and the reticle, the pellicle membrane is lifted, and hence the deformation due to gravity (and its own weight) can be relieved or eliminated.

We have now devised an improved arrangement. Referring to FIG. 2 of the drawings, apparatus according to an exemplary embodiment of the present invention comprises a reticle base plate 5 connected to a frame 3 which extends substantially perpendicularly therefrom. A pellicle membrane 1 is connected to the frame 3, substantially parallel to the reticle base plate, so as to define an enclosure with a space 9 between the reticle carried on the base plate 5 and the pellicle membrane 1. A mask 6 is provided on the reticle within the enclosure.

A bore hole 11 is provided in a side wall of the frame 3 into the enclosure. A mechanism 13 for adjusting the gas pressure in the space 9 to compensate for the effect of gravity on the pellicle membrane 1, comprises a piston member 15 within a housing 17 which is closed at one end, so that a chamber 19 is defined at the closed end of the housing 17. A bore hole 21 is provided in a wall of the housing 17 into the chamber 19 and a tube or pipe 23 between the bore hole 11 and the bore hole 21 defines a gas path between the space 9 and the chamber 19. A moveable piston member 15 determines the necessary gas pressure within the space 9, to compensate for the effect of gravity on the pellicle membrane 1. If friction between the moveable piston member 15 and the housing 17 can be neglected, then:
The part of the surface area of the piston member 15 that is in contact with the gas in chamber 19 will in combination with the weight of the piston member 15 determine the achieved flatness of the pellicle membrane 1.
A change in atmospheric pressure will result only in a movement of the piston member 15, and the pellicle membrane 1 will remain flat.

Friction between the piston member 15 and the housing 17 influences the accuracy of the apparatus and must therefore be minimized.

Fine tuning can be achieved by changing the mass of the piston member 15 by, for example, attaching weights 25 thereto.

In FIG. 3 of the drawings, an example is presented on how friction between the piston member 15 and the inner wall of the housing 17 can be minimized and on how to ensure that there is no absolute gas flow between the piston member 15 and the inner wall of the housing 17. The diameter of the piston member 15 may be significantly less than the inner diameter of the housing 15, such that there is a gap between the piston member 15 and the inner wall of the housing 17. The gap is closed by a flexible membrane 27 connected between the piston member 15 and the inner wall of the housing 17.

It should be noted that the above-mentioned embodiment illustrates rather than limits the invention, and that those skilled in the art will be capable of designing many alternative embodiments without departing from the scope of the invention as defined by the appended claims. In the claims, any reference signs placed in parentheses shall not be construed as limiting the claims. The word “comprising” and “comprises”, and the like, does not exclude the presence of elements or steps other than those listed in any claim or the specification as a whole. The singular reference of an element does not exclude the plural reference of such elements and vice-versa. The invention may be implemented by means of hardware comprising several distinct elements, and by means of a suitably programmed computer. In a device claim enumerating several means, several of these means may be embodied by one and the same item of hardware. The mere fact that certain measures are recited in mutually different dependent claims does not indicate that a combination of these measures cannot be used to advantage.

1. Apparatus for protecting a reticle used for semiconductor chip fabrication, the apparatus comprising an enclosure defined by a pellicle membrane (1) disposed over said reticle with a space (9) therebetween, and means (13) for adjusting gas pressure in said space (9) to compensate for the effect of gravity on said pellicle membrane (1), the apparatus being characterized in that said means (13) for adjusting gas pressure comprises a piston arrangement comprising a piston member (15) within a housing (17) so as to define a chamber (19), said chamber (19) being in gas communication with said space (9) between said pellicle membrane (1) and said reticle, whereby movement of said piston member (15) results in an adjustment in gas pressure within said enclosure so as to compensate for the effect of gravity on said pellicle membrane (1).

2. Apparatus according to claim 1, wherein the piston arrangement includes a housing (17) which is closed at one end and within which the piston member is disposed to define a chamber (19) at the closed end.

3. Apparatus according to claim 1, wherein a wall of the chamber (19) is provided with an aperture (21).

4. Apparatus according to claim 3, wherein the chamber (19) is connected via said aperture (21) by a pipe or tube (23) to said enclosure via an aperture (11) in a side wall thereof.

5. Apparatus according to claim 1, wherein said piston member (15) has a diameter less than the inner diameter of the housing (17) said piston member (15) being connected to the inner side walls of the housing (17) in an air-tight manner for example by means of a flexible membrane (27).

6. Apparatus according to claim 1, comprising means (25) to change the mass of the piston member (15).

7. Apparatus according to claim 6, wherein the means to change the mass of the piston member (15) comprises one or more weights (25), which can be selectively added to or removed from the piston member (15).

8. Apparatus according to claim 1, wherein the pellicle membrane (1) is formed of silicon glass.

9. Apparatus according to claim 1, comprising a reticle base plate (5) on which the reticle is supported, and a support frame (3) to which the reticle base plate (5) and the pellicle membrane (1) are connected.

10. A method of protecting a reticle used for semiconductor chip fabrication, the method comprising the steps of providing a pellicle membrane (1) over said reticle so as to define an enclosure with a space (9) therebetween, and adjusting gas pressure in said space (9) to compensate for the effect of gravity on said pellicle membrane (1), the method being characterized in that said step of adjusting gas pressure comprises the steps of providing a piston arrangement comprising a piston member (15) within a housing (17) so as to define a chamber (19), said chamber (19) being in gas communication with said space (9) between said pellicle membrane (1) and said reticle, whereby movement of said piston member (15) results in an adjustment in gas pressure within said enclosure so as to compensate for the effect of gravity on said pellicle membrane (1).

11. A method of manufacturing a semiconductor chip, the method comprising providing a reticle and apparatus according to claim 1, providing a patterned mask (6) on said reticle, and irradiating said reticle through said pellicle membrane (1) and said mask (6).

12. A semiconductor chip fabricated according to the method of claim 11.
